(19) United States
(12) Patent Application Publication
(10) Pub. No.: US 2009/0065936 A1
(43) Pub. Date: Mar. 12, 2009

(54) SUBSTRATE, ELECTRONIC COMPONENT, ELECTRONIC CONFIGURATION AND METHODS OF PRODUCING THE SAME

(76) Inventors: Jenny Wai Lian Ong, Singapore (SG); Chor Fan Chan, Singapore (SG); Chui Har Lam, Singapore (SG)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/908,734

(22) PCT Filed: Mar. 16, 2005
(86) PCT No.: PCT/IB2005/000672

§ 371 Date: May 23, 2008

(51) Int. Cl. H01L 23/488; H01L 21/58

(52) U.S. Cl. 257/738; 438/125; 257/E23.023; 257/E21.505

(57) ABSTRACT

A substrate for an electronic component comprises a dielectric body having an upper surface including a plurality of inner contact pads and a lower surface including a plurality of outer contact pads. Each outer contact pad has an inner face and an outer face. An insulating layer covers the lower surface of the dielectric body and the peripheral regions of the plurality of outer contact pads. A depression is located in the approximate lateral centre of the outer face of each of the plurality of outer contact.

### CROSS-REFERENCE TO RELATED APPLICATIONS

This Utility Patent Application claims priority to PCT Application No. IB2005/000672, filed Mar. 16, 2005, which is herein incorporated by reference.

### BACKGROUND

The present invention relates to substrates for electronic components, such as semiconductor packages, to electronic components and electronic configurations as well as to methods for fabricating substrates and assembling electronic components and electronic configurations.

Semiconductor packages including a semiconductor chip are typically mounted on a substrate such as a printed circuit board (PCB) by the external contacts of the package. These external contacts may be pins, leads or solder balls depending on the type of package. Typically, the printed circuit board also includes other electronic components which are electrically connected by conductor tracks located on or within the PCB to form an electronic subsystem. Such subsystem boards are widely used.

Printed circuit board including semiconductor packages suffer from the problem that the joints between the package and the board can fail. This may be caused by thermal cycling or due to the different thermal expansion coefficients.

The problem of crack formation in the metallurgical contacts is addressed by U.S. Pat. No. 6,696,757 which provide a contact which includes a castellated contact pad. However, these contact pads are complex and expensive to produce and, therefore, the cost of the package is undesirably increased.

In many consumer goods including printed circuit boards with electronic components and semiconductor packages, such as mobile telephones for example, the printed circuit board and the semiconductor packages mounted on the printed circuit board undergo repeated mechanical stress. Mechanical stress may also lead to failure of the subsystem due to the delamination of the package from the printed circuit board.

### SUMMARY

An embodiment provides a substrate for an electronic component, in particular a semiconductor package, an electronic component and electronic configurations which can better withstand mechanical stress and which can also be manufactured inexpensively.

It is a further embodiment to provide methods for the fabrication of substrates for electronic components and methods for the assembly of electronic components and electronic configurations.

An embodiment provides a substrate for an electronic component which includes a dielectric body having an upper surface and lower surface. The dielectric body is provided in the form of a dielectric board. The substrate further includes a plurality of inner contact pads disposed on the upper surface and a plurality of outer contact pads disposed on the lower surface.

The substrate also includes a plurality of conductor tracks disposed on the upper and lower surfaces and vias located in the body of the substrate. The inner contact pads and electrically connected to the outer contact pads by the conductor tracks and vias and provide the electrically conductive rewiring or redistribution structure of the substrate. Each outer contact pad has an inner face and an outer face. The inner face of each of the outer contact pads is level and lies in a single plane. Essentially, the whole of the single plane, inner face is in contact with the lower surface of the dielectric body.

The substrate further includes an insulating layer covering the lower surface of the dielectric body and the peripheral regions of the plurality of outer contact pads. The central portion of the outer contact pads remains free from the insulating layer. The insulating layer is a solder resist layer. A solder resist layer includes a material which is not wetted by solder. This prevents solder from flowing away from the contact areas during the solder reflow process and prevents short circuits between adjacent contact areas or conductor tracks for example.

The plurality of outer contact areas each include a depression or recess which is located in the outer face of each of the plurality of outer contact pads. Each depression has a base and at least one side wall and is located in the approximate lateral centre of the outer face of the outer contact pad.

The depression of each of the outer contact pads remains free from the insulating or solder resist layer and, therefore, provides the electrically conductive surface of the outer contact pad. The depression, therefore, has a depth which is less than the thickness of the peripheral region of the outer contact area.

Alternatively, the outer contact pad is described as including a base portion including an annular protrusion situated at the periphery of the base portion. The outwardly facing surfaces of the annular protrusion are covered by the insulating layer.

The provision of a depression in the outer face of each of the outer contact pads provide a more reliable interface between the solder ball, which will be attached to the outer contact pads, and the outer contact pad itself. The substrate is a laminate substrate and is used in ball grid array (BGA) type packages.

The outer contact pads including a depression can be fabricated using existing equipment and existing materials. Therefore, the use of alternative materials, in particular alternative alloy compositions of the solder avoided. This reduces the cost of the substrate and ultimately the cost of the electronic component or semiconductor package.

Also, the use of an additional underfill material between the package and the printed circuit board can be avoided. This is particularly as this additional process has to be performed by the customer. Therefore, an embodiment provides a more reliable substrate which can be more simply handled by the customer. This also increases the reliability of the package.

Typically, the substrate includes a plurality of outer contact pads, each having a depression or recess located in the outer face of the outer contact pad. The outer contact pad and depression of each of the plurality of outer contact pads is essentially the same. The depression is concentrically positioned in the outer face of each of the outer contact pads. With this, the mechanical stress is more uniformly distributed as the ball thickness of the annular protrusion is essentially the same at all points around the ring.

The depression and the outer contact pad are laterally essentially circular. As such, a reliable joint can be formed between the solder ball and the inner surfaces, that is the base and inner side walls, of the outer contact pad. Since, during the solder reflow process, the effects of surface tension result in the solder ball tending to form a sphere. Therefore, an essentially laterally circular depression provides a more uniform contact between the solder ball and the inner surfaces of the depression and, therefore, provides a more uniform distribution of stress and a more reliable joint.

In an alternative embodiment, the side wall of each depression further includes at least one process. The provision of a process in the side wall in creases the interfacial surface area between the outer contact pad and the solder ball. Therefore, a more reliable joint can be provided. Each depression is laterally smaller at the base than at the plane of the outer face of the outer contact area. This structure is easily fabricated by etching techniques for example.

The process is concentrically positioned in the side wall. The process, therefore, has approximately the same width along the whole of its length. This enables a more even distribution of mechanical stress and a more uniform interfacial surface area between the outer contact pad and the solder ball.

The outer contact pad, includes copper or a copper alloy and the dielectric body, includes a BT-resin or FR4. These materials are widely used and inexpensive. They are, therefore, easy to use in the existing manufacturing line so that costs are not increased.

The substrate of the embodiment is provided as a panel. The panel includes a plurality of component or package positions, each component position provides a substrate for a single component. The component positions are typically arranged in a matrix grid of rows and columns. Adjacent component positions are separated by singulation trenches or saw streets. Typically, a semiconductor package is assembled on each of the package positions of the panel and then the packages are singulated from the panel, typically, by a sawing process.

In an alternative embodiment, the substrate further includes a plurality of solder balls. A solder ball is disposed on each of the outer contact pads. At least part of the solder ball is located within the depression of each of the outer contact pads and is in contact with and electrically connected to, the base and inner side walls of the depression. The side wall of the depression, therefore, laterally surrounds at least part of the solder ball.

The solder ball, therefore, has a volume which is larger than the volume of the cavity formed by the depression. Therefore, only the portion of the solder ball facing towards the outer contact pad is located within the depression and the outer portion of the solder ball protrudes from the depression. The protruding outer portion enables the solder ball to be connected to an external substrate such as a printed circuit board.

An embodiment also provides an electronic component including a substrate according to one of the embodiments previously described. The electronic component also includes a semiconductor chip having an active surface with chip contact pads and a passive surface. The semiconductor chip is mounted on the upper surface of the substrate. The electronic component further includes a plurality of electrical connections which electrically connect the semiconductor chip to the inner contact pads positioned on the upper surface of the substrate. An electrical connection is in electrical contact with each of the chip contact pads and a corresponding inner contact on the upper surface of the substrate.

The electronic component also includes a plurality of solder balls. As previously described, a solder ball is disposed on each of the outer contact pads and at least part of the solder ball is located within the depression of each of the outer contact pad. The side wall of the depression laterally surrounds at least part of the solder ball.

The electrical connections may include solder bumps or balls so that the semiconductor chip is mounted by a flip-chip technique on the upper surface of the substrate. In this embodiment, the inner contact pads of the substrate are located towards the centre of the upper surface and have a lateral arrangement which corresponds to the lateral arrangement of the chip contact pads.

Alternatively, the electrical connections include bond wires. In this embodiment, the inner contact areas of the substrate are located towards the periphery of the upper surface and laterally surround the semiconductor chip. The passive surface of the semiconductor chip is mounted on the upper surface of the substrate. The outer contact areas of the substrate can be of any of the embodiments previously described.

The semiconductor chip and upper surface of the substrate may also be encapsulated in a plastic molding compound, typically an epoxy-based resin. This encapsulation protects the chip from mechanical damage and from the environment.

An embodiment also provides an electronic configuration which includes an electronic component according to one of the embodiments already described and a circuit board. The circuit board includes a plurality of component contact areas on its upper surface and a plurality of conductor tracks which enable the electronic component to be electrically connected to other components. The electronic component is mounted on the circuit board by the plurality of solder balls. A solder ball is disposed between each outer contact pad of the substrate of the electronic component and a component contact area of the circuit board.

An embodiment provides a more reliable electronic configuration due to the improved reliably of the solder joints formed between the outer contact pads of the laminate substrate and the solder balls. Therefore, the reliability of the joint formed between the electronic component and the component contact areas. The likelihood of failure of the electrical contact is reduced.

An embodiment also relates to methods of fabricating a substrate. A dielectric body having an upper surface and a lower surface is provided. The dielectric body is a dielectric board. A plurality of precursor outer contact pads are provided on the lower surface of the dielectric body.

The precursor outer contact pads may be deposited using a masking and deposition technique or, alternatively, by depositing a closed layer and removing the undesired areas to leave the precursor outer contact pads. The precursor outer contact pads have a thickness which is approximately that of the desired thickness of the peripheral regions of the final outer contact pads of the package. The outer surface of the precursor contact pad is level and uniform and lies in a plane parallel to the lower surface of the substrate.

A plurality of depressions are then formed, a depression being formed in the approximate lateral centre of each of the plurality of outer contact pads to form a contact pad according to an embodiment previously described.

An insulating layer is then deposited on the lower surface of the dielectric body. The plurality of depressions remain uncovered by the insulating layer. The insulating layer is a solder resist layer and includes apertures or through-openings positioned in alignment with the plurality of depressions. The periphery of the outer face of the depression is covered by the insulating layer. The insulating layer, therefore, has a thickness which is greater than the thickness of the periphery of the outer contact pad and greater than the thickness of the precursor outer contact pad.

The plurality of depressions can be formed by the following method. A first structured photoresist layer is deposited on the lower surface of the dielectric body. The central portion of the precursor outer contact pads remains free from the first photoresist layer. A depression in the uncovered portion of each of the precursor outer contact pad is then formed by an etching process. The first photoresist layer is removed and a second photoresist layer is applied.

The second photoresist layer essentially covers the depressions in the outer contact pads but leaves the remaining areas of the lower surface and the outer peripheral face of the outer contact pads exposed. The insulating layer is then applied to the lower surface of the dielectric body and, afterwards, the second photoresist layer is removed to expose the depressions in the outer contact pads.

In an alternative embodiment, the method may also include the further process of forming a process in the side wall of each of the depressions. The process is formed by applying a third structured photoresist layer to the lower surface of the dielectric body. The central portion of each of the depressions already formed in the outer contact area remains uncovered by the third photoresist layer. A second depression is then formed in the uncovered region of each of the outer contact pads by an etching process. The third structured photoresist layer is then removed.

The etching process to form both the first and, in an alternative embodiment, also the second depressions in the outer contact pads is performed by a chemical etching process or they plasma etching technique.

An embodiment also relates to methods of assembling an electronic component. A method includes the processes of providing a substrate according to one of the embodiments already described. A semiconductor chip having an active surface and a plurality of chip contact pads positioned on the active surface is also provided.

The semiconductor chip is then mounted on the upper surface of the substrate and electrical connections are made between the chip contact pads and the inner contact pads positioned on the upper surface of the substrate. A solder ball is placed on each outer contact pad positioned on the lower surface of the substrate.

As previously described, at least part of the solder ball is located within the depression positioned in each of the outer contact pads. The solder ball is in contact with and electrically connected to the base and side wall of the depression. The side wall of the depression, therefore, laterally surrounds at least part of the solder ball.

The electrical connections are, in one embodiment, provided by solder balls of flip-chip contacts positioned between each of the chip contact pads and inner contact pads of the substrate. In a second embodiment, the electrical connections are provided by forming bond wires between each of the chip contact pads and an inner contact pad.

An embodiment also relates to methods of assembling an electronic configuration. Firstly, an electronic component such as a semiconductor package which includes a substrate as previously described, is provided. A circuit board, a printed circuit board, is provided. A plurality of component contact areas and electrically conducting conductor tracks are disposed on the upper surface of the circuit board.

The electronic component is mounted on the circuit board by the plurality of solder balls. A solder ball is disposed between each outer contact pad of the substrate of the electronic component and a component contact area disposed on the upper surface of the circuit board. A solder reflow process is then performed to provide the electrical connection between the component and the printed circuit board.

An embodiment, therefore, provides a laminate substrate for a semiconductor device, and is used in a ball grid array type integrated circuit. The peripheral regions of the outer contact pad or solder pad are surrounded by, and covered with, an insulating layer which is a solder resist layer. According to an embodiment, a depression or recess is provided in the approximate lateral centre of the outer face of each of the contact pads.

The outer contact pad, according to an embodiment, is thought to move the weakest intermetallic interface away from the area of greatest stress concentration thereby reinforcing the weakest metallic interface and providing a more reliable joint. It is through that the interface between the outer contact area and the solder ball may be the weakest into metallic interface Analysis of drop tests indicates that the peeling stress (SZ) and equivalent stress according to von Mises (SEQV) at the interface between the outer contact area of the substrate, according to an embodiment, and the solder ball is reduced by 12 to 14% compared to a substrate including conventional contact pads. A more reliable package, which is better able to withstand mechanical stress, is, therefore, provided.

For these and other reasons there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a ball grid array (BGA) semiconductor package having outer contact pads according to a first embodiment.

FIG. 2 illustrates a portion of a laminate substrate including an outer contact pad according to a second embodiment.

FIGS. 3 to 8 illustrate processes in the fabrication of an outer contact pad according to the embodiment of FIG. 1.

FIG. 3 illustrates a section of a laminate substrate including a precursor outer contact pad.

FIG. 4 illustrates the application of a first photoresist layer to the precursor outer contact pad of FIG. 3.

FIG. 5 illustrates the etching of the depression in the precursor contact pad of FIG. 4.

FIG. 6 illustrates the application of a second photoresist layer to the depression formed in the method process of FIG. 5.

FIG. 7 illustrates the deposition of a solder resist layer on the structure of FIG. 6.

FIG. 8 illustrates the removal of the second photoresist layer.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

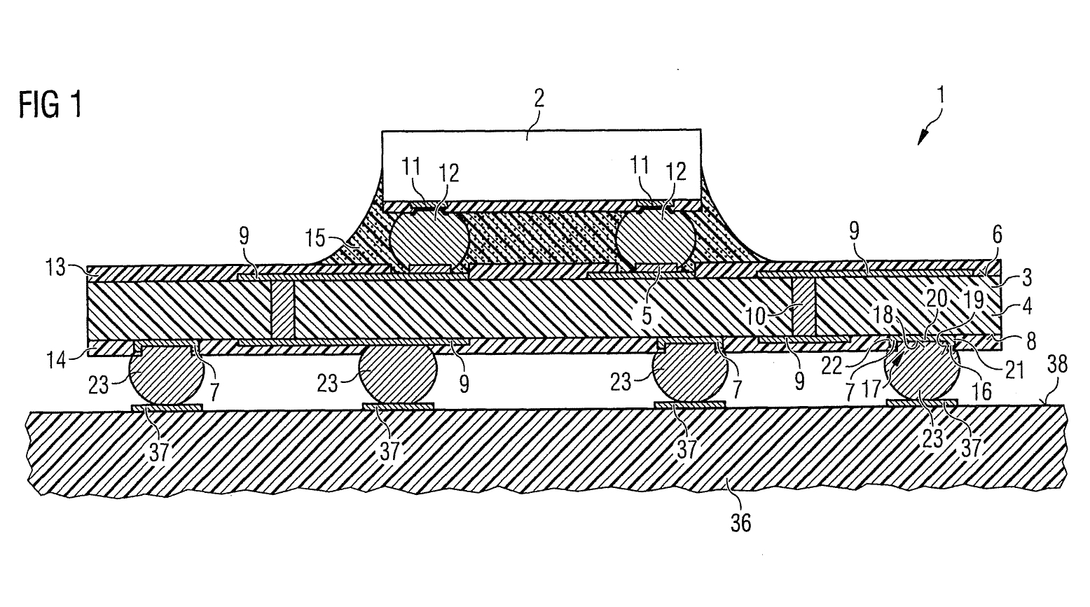

FIG. 1 illustrates a ball grid array (BGA) semiconductor package 1 according to a first embodiment. The semiconductor package 1 includes a semiconductor chip 2 which is mounted on a laminate substrate 3.

The laminate substrate 3 includes a dielectric board 4 of FR4 material. A plurality of inner contact areas 5 are positioned on the upper surface 6 of the dielectric board 4 towards the lateral centre. The plurality of inner contact areas 5 are electrically connected to outer contact areas 7 disposed on the lower surface 8 of the dielectric board 4 by conductive tracks 9, disposed on the upper surface 6 and lower surface 8, and vias 10 which stretch from the upper surface 6 to the lower surface 8 of the dielectric board 4. The conductor tracks 9 and vias 10 include copper and provide the electrically conducting rewiring structure of the laminate substrate 3.

The semiconductor chip 2 has an active surface which includes integrated circuit devices and a plurality of chip contact pads 11. A flip chip contact 12, in this case a solder ball, is disposed between each chip contact pad 11 and an inner contact pad 5 located on the upper surface 6 of the laminate substrate 3. Therefore, the lateral arrangement of the inner contact pads 5 is essentially the same as, and corresponds to, the lateral arrangement of the chip contact areas 11. In the cross-sectional view of FIG. 1, only two of the plurality of flip-chip contacts 12 are illustrated for clarity.

In the semiconductor package 1, the laminate substrate 3 is laterally larger than the semiconductor chip 2. As the outer contact areas 7 are disposed across the whole of the width and breadth of the lower surface 8 of the laminate substrate 3, the wiring structure provides a “fan out” redistribution structure. This describes that the distance between adjacent outer contacts areas 7, known as the pitch, is greater than the pitch between adjacent inner contact areas 5.

The upper surface 6 and lower surface 8 of the dielectric board 4 also include a respective upper 13 and lower 14 solder resist layer. The solder resist layer 13 disposed on the upper surface 6 of the dielectric board 4 covers the conductor tracks 9 but leaves the inner contact areas 5 uncovered.

In the semiconductor package 1 of FIG. 1, the cavity formed between the active surface of the semiconductor chip 2 and the upper surface of the solder resist layer 13 is underfilled by underfill material 15. In this embodiment, the underfill material includes an epoxy-based underfill material with filler particles.

The second solder resist layer 14 disposed on the lower surface 8 of the dielectric board 4 of the laminate substrate 3 covers the conductor tracks 9 and the peripheral regions of the outwardly facing surface 16 of the outer contact areas 7. The lower solder resist layer 14, therefore, includes openings or apertures which are positioned in approximately the lateral centre of each outer contact pad 7.

In a first embodiment, each of the plurality of outer contact pads 7 includes a depression 17 which is positioned in the outer face 16 of each of the outer contact pads 7. A detailed view of an outer contact pad 7 according to the first embodiment, is also illustrated in FIG. 8. Each of the pluralities of outer contact pads 7 and depressions 17 of the laminate substrate 3 are essentially the same. Each depression 17 has a base 18 which lies in a plane essentially parallel to the lower surface 8 of the dielectric board 4 and side walls 19 which lie in a plane essentially perpendicular to the base 18. Essentially is used in this context to include small deviations from an exactly parallel or perpendicular plane.

Although this cannot be seen in the cross-sectional view of FIG. 1, each outer contact pad 7 is laterally essentially circular and the depression 17 is also laterally essentially circular. The depression 17 is positioned concentrically in the lateral centre of the outer surface 16 of the contact pad 7. Each outer contact pad 7, therefore, includes a thin base portion 20 and an annular protrusion 21. The annular protrusion 21 is positioned at the periphery of the base portion 20 of the contact pad 7.

The outwardly facing the surfaces 22, 16 of the outer contact pads 7 and, therefore, the outer surface of the annular protrusion 21 are covered by the solder resist layer 14. The depression 17, including the base 18 and inwardly facing side wall 19, remains free from the lower solder resist layer 14. The apertures positioned in the lower solder resist layer 14 are of essentially the same lateral size as the depressions 17 and which are located in the solder resist layer 14 in alignment with the depressions 17.

An external contact 23, in this case a solder ball, is disposed on each outer contact pad 7. The inner portion of each solder ball 23, i.e. The portion of the solder ball 23 facing towards the outer contact pad 7 and lower surface 8 of the laminate substrate 3, is disposed in the depression 17 of the outer contact pad 7. The annular protrusion 21, therefore, surrounds the inner portion of the solder ball 23. The solder ball 23 is in mechanical contact with, and electrically connected to, the base 18 and side walls 19 of the depression 17.

The semiconductor package is depicted as mounted on and electrically connected to a higher level printed circuit board 36. A plurality of component contact areas 37 are disposed on the upper surface 38 of the printed circuit board 36 along with a plurality of conductor tracks(which are not illustrated in the figure). The conductor tracks enable the semiconductor package 1 to be accessed and to communicate with other electronic components mounted on the board 36.

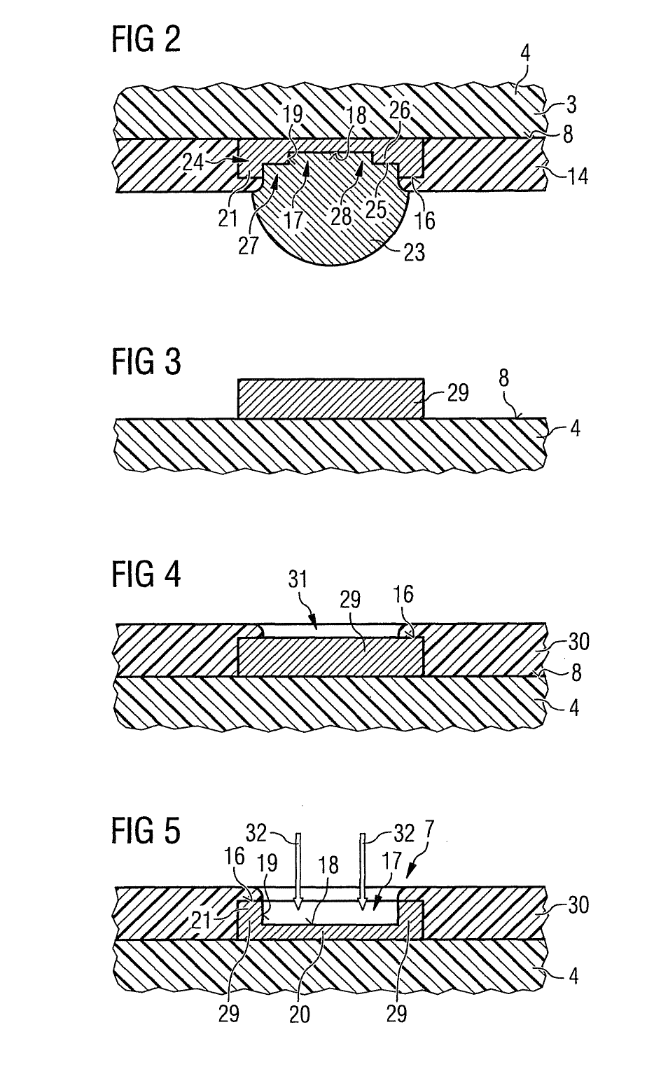

FIG. 2 depicts a portion of a laminate substrate 3 including an outer contact pad 24 according to a second embodiment. The outer contact pad 24 is disposed on the lower surface 8 of the dielectric board 4. The outer contact pad 24 also includes a depression 17 located in its outer surface 16. Similarly to the embodiment illustrated in FIG. 1, the depression 17 is positioned in approximately the lateral centre of the outer contact area 24. The outer contact pad 24 and the depression 17 are essentially circular and the depression 17 is located concentrically in the outer face 16 of the outer contact pad 24.

The depression 17 has a base 18 which lies in a plane essentially parallel to the plane of the lower surface 8 of the dielectric board 4. In the embodiment illustrated in FIG. 2, the side wall 19 of the depression 17 further includes a process 25. The process 25 is concentrically positioned with respect to the base 18 and outer side surface 22 of the outer contact area 24. The process 25 is, therefore, an annular ring.

The depression 17 includes a protrusion 26 positioned in the edge formed between the base 18 and the side wall 19. The protrusion 26 has the form of an annular ring. The outer facing surface 27 of the protrusion 26 provides the process 25 in the side wall 19. The tread of the process 25 lies in a plane essentially parallel to the plane of the base 18. The side wall 19, therefore, has two portions, a lower portion and an upper portion. Each portion lies in a plane essentially perpendicular to the base 18. The lateral distance between opposing points on the lower portion is, therefore, smaller than the distance between opposing points on the upper portion of the side wall.

The depression 17 of the second embodiment can also be described as including two laterally circular depressions 27, 28. A first depression 27 is positioned in the outer surface 16 of the outer contact pad 24. The second depression 28 is laterally smaller than the first depression 27 and is located concentrically in the base of the first depression 27 which is located in the outer face 16 of the outer contact area 24. The remaining peripheral region of the base of the first depression 27 adjoins the upper portion of the side wall 19 of the first depression and provides the process 25.

A solder ball 23 is located in the depression 17 of the outer contact area 24 and is in contact with the base 18, side wall 19 and process 25 of the depression 17. The peripheral annular protrusions 26 and 21, therefore, surround the inner portion of the solder ball 23. The inner surfaces of the annular protrusions 26 and 21 are, therefore, in mechanical and electrical contact with the solder ball 23. The outer surface 16 of the protrusion 21 is covered by the solder resist layer 14. The solder ball 23 is, therefore, electrically connected to the outer contact pad 24.

A method to fabricate a plurality of outer contact pads 7, as illustrated in FIG. 1, will now be described with reference to FIGS. 3 to 8. Only one outer contact pad 7 is depicted in the portion of the laminate substrate 3 illustrated in FIGS. 3 to 8 for clarity. Although the process is described in terms of one outer contact pad, the process processes are carried out in parallel, i.e. essentially simultaneously, for all of the outer contact pads 7 located on the lower surface 8 of the dielectric board 4.

FIG. 3 illustrates the first stage in the method and illustrates a portion of a laminate substrate 3. A plurality of precursor outer contact pads 29 are deposited on the lower surface 8 of the dielectric board 4 of the laminate substrate 3. The precursor outer contact pads 29 are laterally essentially circular and have a defined thickness. The precursor pads 29 have a lateral arrangement which is essentially the same as that desired for the outer contacts 23 of the semiconductor package. The lateral arrangement of the outer contacts, in this case solder balls, of the package is typically dictated by agreed industry standards.

FIG. 4 illustrates the deposition of a first photoresist layer 30 on the lower surface 8 of the dielectric board 4. A photoresist material is a material which can be structured by photolithographic techniques. The first photoresist layer 30 has a thickness which is greater than the thickness of the precursor contact pad 29. The first photoresist layer 30 includes a plurality of through-openings or apertures 31. One aperture 31 is arranged on the lateral centre of each outer face 16 of the precursor contact pad 29.

The lateral size of the aperture 31 is smaller than that of the precursor contact pad 29 so that the peripheral regions of the outer surface 16 are covered by the photoresist layer 31 and the central area of the outer face 16 remains exposed from the photo resist layer 30. In this embodiment, the aperture is laterally circular and arranged concentrically on the outer surface 16 of the precursor outer contact pad 29.

FIG. 5 illustrates the next stage in the fabrication process. In this process, the exposed portion of the precursor outer contact pad 29 is subjected to a chemical etching treatment as indicated by the arrows 32. Material is removed from the exposed area and a depression 17 is formed in the centre of the outer face 16 of the precursor contact pad 29. By control of the etching parameters, a depression 17 is formed which has a base 18 which lies in a plane essentially parallel to the lower surface 8 of the dielectric board 4 and a side wall 19 which lie in a plane essentially perpendicular to the base 18. The outer contact pad 7 is, therefore, formed which includes a base portion 20 with a protruding annular ring 21 at its lateral periphery. The outer surface 16 of the protruding ring 21 is covered by the photoresist layer 30.

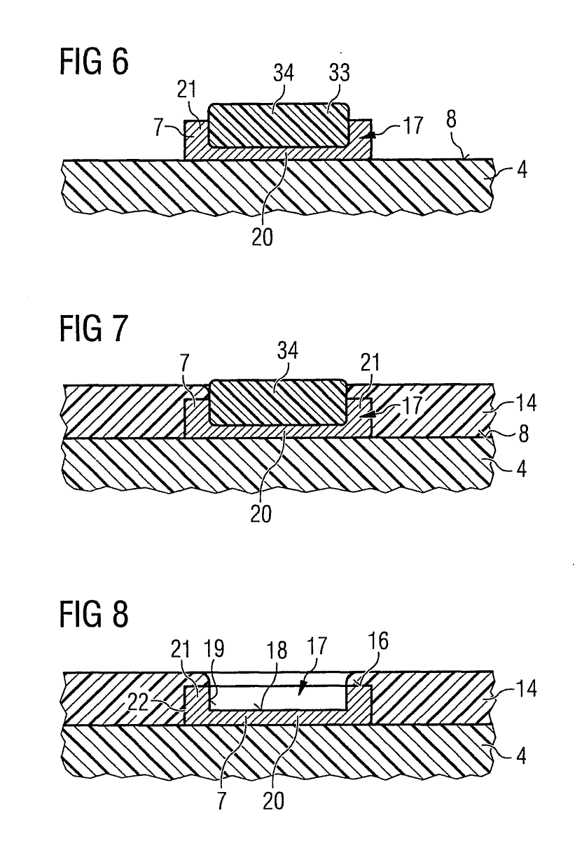

FIG. 6 illustrates the next stage in the method. The first photoresist layer 30 is then removed and a second structured photoresist layer 33 is applied to the lower surface 8 of the dielectric board 4.

As can be seen in FIG. 6, the second structured photoresist layer 33 includes isolated portions 34 of photoresist which fill the depression 17 but leave the outer surface 16 of the protrusion 21 and the upper surface 8 of the dielectric board 4 exposed. The isolated protrusion 34 of the second photoresist layer 33 has a thickness which is greater than the depth of the depression 17. The isolated portions 34 of the second photoresist layer 33, therefore, protrude above the outer surface 16 of the periphery of the outer contact pad 7. The outer side wall of the protrusion is essentially perpendicular to the outer face 16.

FIG. 7 illustrates the next stage in the method. A solder resist layer 14 is deposited on the lower surface 8 of the dielectric board 4. The solder resist layer 14 covers the lower surface 8 of the dielectric board 4, the outer side walls 22 and the outer face 16 of the protruding peripheral region of the outer contact pad 7. The solder resist layer 14, therefore, includes apertures 35 whose size and lateral arrangement corresponds to, and is essentially the same as, the protrusions 34 of the photoresist layer 33.

In the next stage of the process, as depicted in FIG. 8, the second photoresist layer 33 is removed to leave the outer contact area 7 disposed on the lower surface 8 of the dielectric board. The contact pad 7 includes a depression 17 located in its approximate lateral centre which is exposed from the solder resist 14. The outer contact pad 7 includes a peripheral protruding annular ring 21 which is covered by the solder resist layer 14.

The outer contact pad 24 according to a second embodiment illustrated in FIG. 2 is fabricated using a similar process which is not illustrated in the figures.

Essentially, the process of FIGS. 3 to 5 is carried out to produce a first depression 27 in the outer face 26 of the of the precursor outer contact area 29. Then a third structured photoresist layer is deposited on the lower surface 8 of the dielectric board which covers the peripheral regions of the protruding portion 21 of the first depression 17 and the peripheral regions of the base of the first depression.

A second etching process is then performed to form a second depression in the exposed central portion of the base of the first depression. After the photoresist has been removed, a depression 17 is formed in which the side wall 19 has a process. A solder resist layer 14 is then deposited on the lower surface in a similar way to that illustrated in FIGS. 6 to 8 which leaves the inner surfaces of the depression exposed.

The laminate substrate 3 including the outer contact areas 7, 24 fabricated as illustrated in FIGS. 3 to 8 is then used in the assembly of semiconductor packages. Typically, the laminate substrate is fabricated in the form of a large board which includes a number of component positions arranged in rows and columns. A semiconductor package is assembled on each component position.

Firstly, a semiconductor chip is mounted on the upper surface of each component position and electrically connected to the substrate. The electrical connections may be provided by flip chip contacts in which case the active surface of the semiconductor chip faces the upper surface of the substrate. Alternatively, the electrical connections may be provided by bond wires. In this case, the passive surface of the chip is attached to the upper surface of the substrate by die attach material.

The chip and electrical connections may then be encapsulated by an epoxy-based mold material in order to provide protection from mechanical stress and environmental damage. The individual packages are then singulated from the panel. The packages are tested and shipped to the user who typically mounts the package on a higher level circuit board such as a printed circuit board. The mechanical and electrical connection between the package and the PCB is provided by reflowing the solder balls.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

1-19. (canceled)

20. A electronic component including a substrate comprising:
a dielectric body having an upper surface and a lower surface;
a plurality of inner contact pads disposed on the upper surface;
a plurality of outer contact pads disposed on the lower surface, each outer contact pad having an inner face and an outer face, the inner face being level and being in contact with the lower surface of the dielectric body;
an insulating layer covering the lower surface of the dielectric body and the peripheral regions of the plurality of outer contact pads; and
a depression located in the outer face of each of the plurality of outer contact pads, each depression having a base and at least one side wall and each depression being located in the approximate lateral centre of the outer face of the outer contact pad.

21. The electronic component of claim 20, wherein the depression is concentrically positioned in the outer face of each of the outer contact pads.

22. The electronic component of claim 20, wherein the depression is laterally essentially circular.

23. The electronic component of claim 20, wherein the side wall of each depression further comprises at least one step.

24. The electronic component of claim 23, wherein each depression is laterally smaller at the base.

25. The electronic component of claim 23, wherein the step is concentrically positioned in the side wall.

26. The electronic component of claim 20, wherein the plurality of outer contact pad comprises copper or a copper alloy.

27. The electronic component of claim 20, wherein the dielectric body comprises BT or FR4.

28. The electronic component of claim 20 further comprising a plurality of solder balls, a solder ball being disposed on each of the outer contact pads, wherein at least part of the solder ball is located within the depression of each of the outer contact pads and the side wall of the depression laterally surrounds at least part of the solder ball.

29. An electronic component comprising:
a dielectric body having an upper surface and a lower surface;
a plurality of inner contact pads disposed on the upper surface;
a plurality of outer contact pads disposed on the lower surface, each outer contact pad having an inner face and an outer face, the inner face being level and being in contact with the lower surface of the dielectric body;
an insulating layer covering the lower surface of the dielectric body and the peripheral regions of the plurality of outer contact pads; and
means in the outer face of each of the plurality of outer contact pads and located in the approximate lateral centre of the outer face of the outer contact pad for providing a base and at least one side wall;
a semiconductor chip having an active surface and chip contact pads positioned on the active surface, the semiconductor chip being mounted on the upper surface of the dielectric body;
a plurality of electrical connections electrically connecting the semiconductor chip to the inner contact pads positioned on the upper surface of the dielectric body; and
a plurality of solder balls, wherein a solder ball is disposed on each of the outer contact pads, and wherein at least part of the solder ball is located adjacent the base of each of the outer contact pad, and wherein the side wall laterally surrounds at least part of the solder ball.

30. The electronic component of claim 29, wherein the electrical connections comprise solder bumps or bond wires.

31. The electronic component of claim 29 further comprising:
a circuit board comprising a plurality of component contact areas on its upper surface, wherein the electronic component is mounted on the circuit board by the plurality of solder balls, a solder ball being disposed between each outer contact pad of the dielectric body, of the electronic component, and a component contact area of the circuit board.

32. A method of fabricating a substrate for an electronic component comprising:
providing a dielectric body having an upper surface and a lower surface;
forming a plurality of precursor outer contact pads on the lower surface of the dielectric body;
forming a plurality of depressions, a depression being formed in the approximate lateral centre of the outer face of each of the plurality of precursor outer contact pads; and
applying an insulating layer to the lower surface of the dielectric body, the plurality of depressions remaining uncovered by the insulating layer.

33. The method of claim 32 wherein forming the plurality of depressions comprises:
applying a first structured photoresist layer to the lower surface of the dielectric body, wherein the central portion of the precursor outer contact pads remains free from the first photoresist layer;
forming a depression in the uncovered portion of each of the precursor outer contact pad by an etching process;
removing the first photoresist layer;
applying a second photoresist layer, the second photoresist layer essentially covering the depressions in the outer contact pads; and
after the insulating layer is applied to the lower surface of the dielectric body, removing the second photoresist layer to expose the depressions in the outer contact pads.

34. The method of claim 32 further comprising forming a step in the side wall of each of the depressions.

35. The method of claim 34 wherein forming the side wall comprises:
applying a third structured photoresist layer to at least the depressions, wherein the central portion of each of the depressions remains uncovered by the third photoresist layer;
forming a second depression in the uncovered portion of each of the outer contact pads by an etching process; and
removing the third structured photoresist layer.

36. The method of claim 32, wherein the etching process is performed by a chemical etching or a plasma etching technique.

37. A method of assembling an electronic component comprising:
providing a dielectric body having an upper surface and a lower surface;
forming a plurality of inner contact pads on the upper surface;
providing a plurality of outer contact pads on the lower surface, each outer contact pad having an inner face and an outer face, the inner face being level and being in contact with the lower surface of the dielectric body;
providing an insulating layer covering the lower surface of the dielectric body and the peripheral regions of the plurality of outer contact pads;
providing a depression in the outer face of each of the plurality of outer contact pads, each depression having a base and at least one side wall and each depression being located in the approximate lateral centre of the outer face of the outer contact pad;
providing a semiconductor chip having an active surface and a plurality of chip contact pads positioned on the active surface;
mounting the semiconductor chip on the upper surface of the dielectric body;
making electrical connections between the chip contact pads and the inner contact pads positioned on the upper surface of the dielectric body; and
placing a solder ball on each outer contact pad, wherein at least part of the solder ball is located within the depression of each of the outer contact pad and the side wall of the depression laterally surrounds at least part of the solder ball.

38. The method of claim 37 further comprising:
providing a circuit board comprising a plurality of component contact areas on its upper surface;
mounting the electronic component on the circuit board by the plurality of solder balls, a solder ball being disposed between each outer contact pad of the dielectric body of the electronic component and a component contact area of the circuit board; and
performing a solder reflow process.
